(19) United States
(12) Patent Application Publication
(10) Pub. No.: US 2014/0261168 A1
(43) Pub. Date: Sep. 18, 2014

(54) MULTIPLE CHAMBER MODULE AND PLATFORM IN SEMICONDUCTOR PROCESS EQUIPMENT

(71) Applicant: Applied Materials, Inc., Santa Clara, CA (US)

(72) Inventors: Qiwei Liang, Fremont, CA (US); Ellie Y. Yieh, San Jose, CA (US); Juan Carlos Rocha-Alvarez, San Carlos, CA (US); Russell Edward Perry, Pleasanton, CA (US)

(21) Appl. No.: 14/162,048

(22) Filed: Jan. 23, 2014

Related U.S. Application Data
(60) Provisional application No. 61/781,552, filed on Mar. 14, 2013.

(51) Int. Cl. H01L 21/67

(52) U.S. Cl. CPC H01L 21/67196
USPC 118/500

(57) ABSTRACT

Embodiments of the present invention generally relate to a cluster tool for processing semiconductor substrates. In one embodiment, a cluster tool having four to six process chambers connected to a transfer chamber and each process chamber may simultaneously process two or three substrates.

### CROSS-REFERENCE TO RELATED APPLICATIONS

This application claims benefit of U.S. Provisional Patent Application Ser. No. 61/781,552, filed Mar. 14, 2013, which is herein incorporated by reference.

### BACKGROUND

1. Field

Embodiments of the present invention generally relate to a cluster tool for processing semiconductor substrates.

2. Description of the Related Art

Substrate throughput in semiconductor processing is always a challenge. If technology is to advance, semiconductor substrates continually need to be processed efficiently. Cluster tools have developed as an effective means for processing multiple substrates simultaneously without breaking vacuum. Instead of processing a single substrate and then exposing the substrate to atmosphere during transfer to another chamber, multiple process chambers can be connected to a common transfer chamber so that when a process is complete on the substrate in one process chamber, the substrate can be moved, while still under vacuum, to another process chamber that is coupled to the same transfer chamber.

To further improving throughput and reducing cost, each process chamber may be able to process more than one substrate at once. Typically, a single process chamber may simultaneously process from four to seven substrates. However, as the size of the substrate increases, the size of such process chamber also increases, and in turn limiting the number of process chambers may be connected to the common transfer chamber. In addition, uniformity may become an issue when there are over five substrates to be processed at once in a process chamber.

Therefore, an improved cluster tool is needed for increasing through put, reducing cost, and maintaining process uniformity.

### SUMMARY

Embodiments of the present invention generally relate to a cluster tool for processing semiconductor substrates. In one embodiment, a cluster tool has four to six process chambers connected to a transfer chamber and each process chamber may simultaneously process two to three substrates.

In one embodiment, a cluster tool for processing semiconductor substrates is disclosed. The cluster tool includes a transfer chamber and four to six process chambers directly connected to the transfer chamber. Each process chamber holds two or three substrates.

In another embodiment, a cluster tool for processing semiconductor substrates is disclosed. The cluster tool includes a transfer chamber and six process chambers directly connected to the transfer chamber. Each process chamber has a central rotary substrate support that holds three substrates. The cluster tool further includes at least one transfer robot disposed in the transfer chamber.

In another embodiment, a cluster tool for processing semiconductor substrates is disclosed. The cluster tool includes a transfer chamber and six process chambers directly connected to the transfer chamber. Each process chamber holds two substrates. The cluster tool further includes a transfer robot disposed in the transfer chamber. The transfer robot has a first arm having a third length and a second arm having a fourth length.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1A is a top view of a process chamber according to one embodiment of the invention.

FIG. 1B is a top view of the process chamber of FIG. 1A at a different depth according to one embodiment of the invention.

FIG. 2A is a top view of a cluster tool according to one embodiment of the invention.

FIG. 2B is a top view of a cluster tool according to one embodiment of the invention.

FIG. 3 is a top view of a cluster tool according to one embodiment of the invention.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present invention generally relate to a cluster tool for processing semiconductor substrates. In one embodiment, a cluster tool has four to six process chambers connected to a transfer chamber and each process chamber may simultaneously process two or three substrates.

FIG. 1A is a top view of a process chamber 100 according to one embodiment of the invention. The process chamber 100 may be a process chamber for processing semiconductor substrates, such as a chemical vapor deposition (CVD) chamber, a plasma enhanced chemical vapor deposition (PECVD) chamber, an atomic layer deposition (ALD) chamber, or any other suitable process chamber. In one embodiment, the process chamber 100 is a CVD chamber. The process chamber 100 has side walls 102 enclosing a central rotary substrate support, such as a turntable 104. The turntable 104 has a plurality of substrate holders 106 for receiving substrates. As the diameter of the substrate increases, for example, from 200 mm to 300 mm to 450 mm or even larger, the turntable will not hold more than three substrates while trying to maximize the number of process chambers may be connected to the transfer chamber. For large substrates having a diameter such as 300 mm, 450 mm or larger, the turntable 104 holds three substrates and up to six such process chambers may be connected to the transfer chamber to form a cluster tool (described in detail below). In one embodiment, a showerhead 107 is disposed above each substrate holder 106.

The shape of the side walls 102 is selected to minimize footprint of the process chamber 100 while maximizing the number of substrates the process chamber 100 may hold. In one embodiment, as shown in FIG. 1A, the side walls 102 form a symmetrical hexagon. Three non-adjacent sides have the same length while the other three non-adjacent sides also have the same length different than the length of the first three non-adjacent sides.

FIG. 1B is a top view of the process chamber 100 at a location below the turntable 104 according to one embodiment of the invention. Chamber counter bores 108 are formed below the turntable 104 to house various process equipment, such as vacuum pumps, heating/cooling lines, stems to support substrate holders 106, and other suitable process equipment.

FIG. 2A is a top view of a cluster tool 200 according to one embodiment of the invention. The cluster tool 200 has four process chambers 100 connected to a transfer chamber 202. The transfer chamber 202 is connected to a factory interface 208 by one or more load lock chambers 206. The factory interface 208 is coupled to one or more substrate storage cassettes 210.

During operation, an atmospheric robot 212 disposed in the factory interface 208 transfers a substrate from the substrate storage cassettes 210 to the load lock chamber 206. The load lock chambers 206, the transfer chamber 202, and the process chambers 100 are all under vacuum during operation. A robot 204 disposed in the transfer chamber 202 transfers the substrate from the load lock chamber 206 to one of the process chambers 100. The substrate is placed on the substrate holder 106 that is closest to the transfer chamber 202. Then the turntable 104 rotates so an empty substrate holder is rotated to the position closest to the transfer chamber 202 and a second substrate is placed thereon. The last empty substrate holder 106 is then rotated to the position closest to the transfer chamber 202 and a third substrate is placed thereon.

After all three substrates are loaded into one of the process chambers 100, a process, such as CVD, begins. During the CVD process, the three substrates remain stationary, or rotate individually by rotating each substrate holder 106, or rotate together by rotating the central substrate support 104, and may be raised to a higher position closer to the showerhead 107 disposed above the substrates. The processing region between the showerheads 107 and the substrates may be partitioned by walls separating each substrate. Alternatively, there may be no walls separating the substrates.

As shown in FIG. 2A, four process chambers 100 are connected to the transfer chamber 202. The process chambers 100 may perform the same process, for example, all four process chambers are depositing a dielectric layer on the substrate using CVD. Alternatively, each process chamber 100 may perform a different process than other process chambers. For example, one or more process chambers may perform a CVD to deposit a dielectric layer on the substrate. The remaining chambers may be thermal process chambers that are used to cure the dielectric layer.

FIG. 2B is a top view of a cluster tool 220 according to one embodiment of the invention. As shown in FIG. 2B, six process chambers 100 are connected to an octagonal shaped transfer chamber 222. Due to the number of process chambers, one or more robots 204 may be disposed in the transfer chamber 222.

FIG. 3 is a top view of a cluster tool 300 according to one embodiment of the invention. The cluster tool 300 has six process chambers 302 connected to a transfer chamber 306. Each process chamber 302 has two substrate holders 304 disposed perpendicular to the transfer chamber 306. The transfer chamber 306 is connected to a factory interface 312 by one or more load lock chambers 310. A robot 314 is disposed in the factory interface 312 to transfer substrates from one or more substrate storage cassettes 316 to the load lock chambers 310.

A robot 308 is disposed in the transfer chamber 306. Each process chamber 302 has a substrate holder that is adjacent to the transfer chamber, and a second substrate holder that is further away from the transfer chamber 306. Thus, the robot 308 may have an arm that is capable of reaching the second substrate holder. In one embodiment, the robot 308 has two arms having different length. The first arm may be long enough to reach the substrate holder that is adjacent to the transfer chamber 306. The second arm maybe longer than the first arm and is capable of reaching the second substrate holder that is further way from the transfer chamber 306.

In summary, a cluster tool is having multiple process chambers is disclosed. The process chamber may be able to process two or three substrates simultaneously and a total four, six or eight process chambers may be included in the cluster tool to improve throughput and reduce cost.

While the foregoing is directed to embodiments of the present invention, other and further embodiments of the invention may be devised without departing from the basic scope thereof, and the scope thereof is determined by the claims that follow.

1. A cluster tool for processing semiconductor substrates, comprising:
a transfer chamber; and
four to six process chambers directly connected to the transfer chamber, wherein each process chamber holds two or three substrates.

2. The cluster tool of claim 1, wherein each process chamber is hexagonal and has a first three sides having a first length and a second three sides having a second length different from the first length.

3. A cluster tool for processing semiconductor substrates, comprising:
a transfer chamber;
six process chambers directly connected to the transfer chamber, wherein each process chamber has a rotary substrate support that holds three substrates; and
at least one transfer robot disposed in the transfer chamber.

4. The cluster tool of claim 3, wherein each process chamber is hexagonal and has a first three sides having a first length and a second three sides having a second length different from the first length.

5. A cluster tool for processing semiconductor substrates, comprising:
a transfer chamber;
six process chambers directly connected to the transfer chamber, wherein each process chamber holds two substrates; and
a transfer robot disposed in the transfer chamber, wherein the transfer robot has a first arm having a third length, and a second arm having a fourth length.

6. The cluster tool of claim 5, wherein the substrate holders are aligned perpendicular to the transfer chamber.
